(19) United States
(12) Patent Application Publication
(10) Pub. No.: US 2010/0213569 A1
(43) Pub. Date: Aug. 26, 2010

(54) INTEGRATED CIRCUITS HAVING FUSES AND SYSTEMS THEREOF

(75) Inventors: Shien-Yang WU, Jhudong Town (TW); Jye-Yen Cheng, Taichung (TW); Wei-Chan Kung, Hsinchu (TW)

Correspondence Address: LOWE HAUPTMAN HAM & BERNER, LLP, 1700 DIAGONAL ROAD, SUITE 300, ALEXANDRIA, VA, 22314, US

(73) Assignee: Taiwan Semiconductor Manufacturing Company, Ltd., Hsinchu (TW)

(21) Appl. No.: 12/638,903

(22) Filed: Dec. 15, 2009

Related U.S. Application Data
(60) Provisional application No. 61/154,194, filed on Feb. 20, 2009.

(51) Int. Cl. H01L 23/525

(52) U.S. Cl. 257/529; 257/E23.147

(57) ABSTRACT

An integrated circuit includes a fuse over a substrate. The fuse has a first end, a second end, and a central portion between the first end and the second end. A first dummy pattern is disposed adjacent to each side of the central portion of the fuse.

### CROSS REFERENCE TO RELATED APPLICATIONS

The present application claims priority of U.S. Application Ser. No. 61/154,194 filed on Feb. 20, 2009, which is incorporated herein by reference in its entirety.

### BACKGROUND

The present disclosure relates generally to the field of semiconductor circuits, and more particularly, to integrated circuits having fuses and systems thereof.

In the semiconductor industry, fuse elements have been widely utilized in integrated circuits for a variety of purposes, such as improving manufacturing yield or customizing a generic integrated circuit. For example, fuse elements can be used to replace defective circuits on a chip with redundant circuits on the same chip, and thus manufacturing yields can be significantly increased. Replacing defective circuits is especially useful for improving manufacturing yield of the memory chips since memory chips consist of a lot of identical memory cells and cell groups. In another example, selectively blowing fuses within an integrated circuit can be utilized to customize a generic integrated circuit design to a variety of custom uses.

### SUMMARY

In accordance with one or more embodiments, an integrated circuit includes a fuse over a substrate. The fuse has a first end, a second end, and a central portion between the first end and the second end. A first dummy pattern is disposed adjacent to each side of the central portion of the fuse.

In another embodiment, a system includes a processor coupled with an integrated circuit. The integrated circuit includes a fuse over a substrate. The fuse has a first end, a second end, and a central portion between the first end and the second end. A first dummy pattern is disposed adjacent to each side of the central portion of the fuse.

These and other embodiments of the present invention, as well as its features are described in more detail in conjunction with the text below and attached figures.

### BRIEF DESCRIPTION OF THE DRAWINGS

The present disclosure is best understood from the following detailed description when read with the accompanying figures. It is emphasized that various features are not drawn to scale and are used for illustration purposes only. In fact, the numbers and dimensions of the various features may be arbitrarily increased or reduced for clarity of discussion.

FIG. 1 is a schematic drawing illustrating an exemplary fuse of an integrated circuit and a plurality of dummy patterns adjacent thereto.

FIG. 2 is a drawing illustrating a simulation pattern corresponding to the fuse pattern of FIG. 1.

FIG. 3 is a drawing illustrating a fuse of an integrated circuit and another exemplary dummy patterns adjacent thereto.

FIGS. 4A-4H are schematic drawings showing various exemplary patterns of potions between fuse ends and central portions.

FIGS. 5A-5F are schematic drawings showing various exemplary patterns of the central portion of the fuse.

FIG. 6 is a drawing showing a relationship between resistance (Ω) and cumulative distribution (%) of exemplary fuses.

FIG. 7 is a schematic drawing showing a portion of an exemplary integrated circuit.

FIG. 8 is a schematic drawing showing a system including an exemplary integrated circuit.

### DETAILED DESCRIPTION

It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or dispositions discussed.

In general, there are many ways to disconnect fuses: disconnection carried out by the action of a laser beam (referred to as a laser fuse); or disconnection carried out by electrical destruction resulting from the production of heat (referred to as an electrical fuse, or E-fuse).

Laser programmable redundancy using laser fuses has been widely used in large-scale memory devices. However, laser repair rates in various structures such as in lower level metal layers is low and the process is complex. For example, an extra mask is needed to form an opening for laser fusing and the process has to be precisely controlled. If a laser fuse is disposed in a lower level layer deep in a chip, the opening will be deeper. The thickness of dielectric of interconnection has to be controlled precisely, which increases the complexity significantly and decreases the repairable rate.

For electrical fusing, a polysilicon strip is formed and patterned. The polysilicon strip is formed by a process forming polysilicon gates. When the complementary metal-oxide-semiconductor (CMOS) technology has advanced from the polysilicon gates to metal gates, an extra process forming the polysilicon strip is added. The extra polysilicon process increases the manufacturing costs. It is also found that a fuse programming ratio, i.e., a final resistance after fusing (R_{fusing}) to an initial resistance (Rᵢₙᵢₜᵢₐₗ), is about 50 or less. Such fuse programming ratio may result in an undesired failure fusing rate or repair rate.

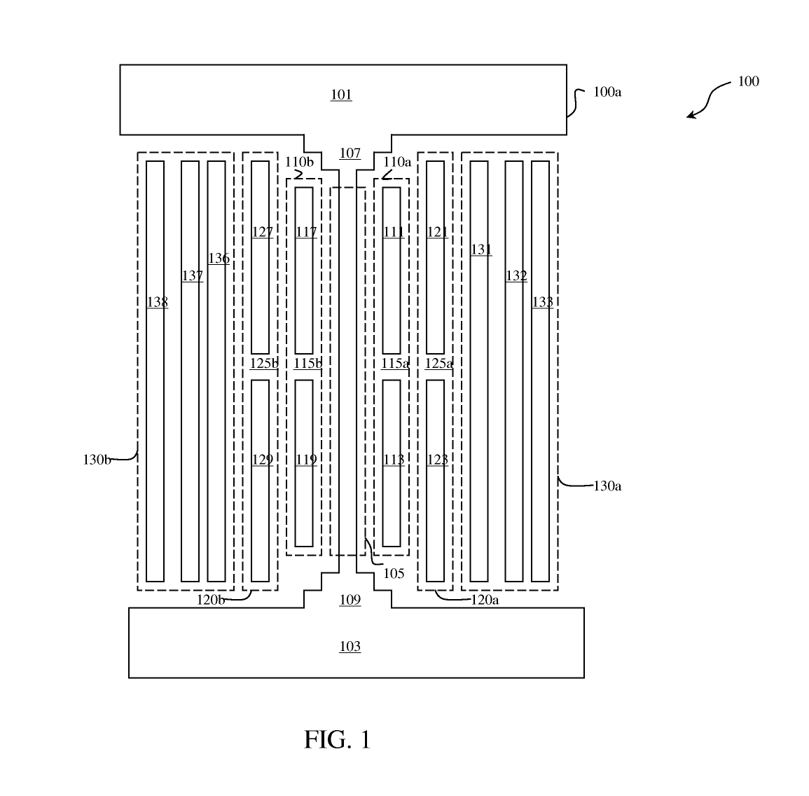

FIG. 1 is a schematic drawing illustrating an exemplary fuse of an integrated circuit and a plurality of dummy patterns adjacent thereto. In FIG. 1, an integrated circuit 100 includes a fuse 100a over a substrate (not shown). The integrated circuit can include a memory circuit, an analog circuit, a digital circuit, a mixed-mode circuit, processor, other integrated circuits, and/or combinations thereof. At least a part of the circuit in the integrated circuit 100 is coupled with the fuse 100a. The substrate is made of semiconductor materials, such as silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In one embodiment, the alloy semiconductor substrate may have a gradient SiGe feature in which the Si and Ge composition change from one ratio at one location to another ratio at another location of the gradient SiGe feature. In another embodiment, the alloy SiGe is formed over a silicon substrate. In another embodiment, a SiGe substrate is strained. Furthermore, the semiconductor substrate may be a semiconductor on insulator, such as a silicon on insulator (SOI), or a thin film transistor (TFT). In some examples, the semiconductor substrate may include a doped epi layer or a buried layer. In other examples, the compound semiconductor substrate has a multilayer structure, or the substrate may include a multilayer compound semiconductor structure.

Referring to FIG. 1, the fuse 100a includes a first end 101, a second end 103, and a central portion 105 between the first end 101 and the second end 103. The first end 101 and the second end 103 of the fuse 100a are coupled with at least one integrated circuit. If a current flowing through the fuse 100a is high enough, the central portion 105 of the fuse 100a melts, which results in the disconnection of the integrated circuit coupled thereto. In embodiments, the fuse 100a has the same material as a metal gate of a field effect transistor (FET), e.g., copper, tungsten, titanium, tantulum, titanium nitride, tantalum nitride, nickel silicide, cobalt silicide; other proper conductive materials; and combinations thereof, a material as same as a metallic layer of interconnection, e.g., copper, aluminum oxide, aluminum, aluminum nitride, titanium, titanium nitride (TiN), tantalum, tantalum nitride, other suitable material, and/or combinations thereof, and/or other suitable metallic material. In at least one other embodiment, the fuse 100a is formed by a process forming a metal gate or a metal interconnection layer, and no extra step of forming an extra polysilicon strip for fusing being necessary.

In one of the embodiments, the integrated circuit 100 includes a first dummy patterns 110a and 110b adjacent to each side of the central portion 105 of the fuse 100a. The patterns of the fuse 100a and first dummy patterns 110a, 110b can be transferred from patterns of at least one mask layer by a photolithographic process. In some embodiments, the fuse 100a is a single line. If the width of the central portion 105 of the fuse 100a is reduced according to technology scaling without a neighboring dummy pattern, the photolithographic process may distort the pattern of the central portion 105 of the fuse 100a, resulting in unexpected variation in critical dimension of the central portion 105 of the fuse 100a. Dummy patterns of the mask layer corresponding to the first dummy patterns 110a and 110b are configured to eliminate or reduce the change in critical dimension of the central portion 105 of the fuse 100a resulting from the photolithographic process or logic operation applied through optical proximate correction (OPC). By adding dummy patterns corresponding to the first dummy patterns 110a and 110b on the mask layer, the lithographic process can better form the pattern of the central portion 105 of the fuse 100a on the substrate at the predetermined dimension.

In some of the embodiments, the first dummy pattern 110a and 110b have lines 111, 113 and 117, 119, respectively. The first dummy pattern 110a has a space 115a between the lines 111 and 113; and the first dummy pattern 110b has a space 115b between the lines 117 and 119. In some embodiments, the spaces 115a and 115b are adjacent to the central portion 105 of the fuse 100a. In other embodiments, the spaces 115a and 115b are adjacent to the center (not labeled) of the central portion 105. If a current flow melts the fuse 100a and the melted fuse material migrates to the lines 111 and/or 113, the space 115a is capable of isolating the line 111 from the line 113, keeping the path of the current flow open. The integrated circuit coupled with the fuse 100a can thus be programmed and/or operate. It is noted that the number and location of the spaces 115a and 115b shown in FIG. 1 are mere examples. One of skill in the art is able to change the number and/or modify the location to achieve a desired fuse element.

Referring to FIG. 1, in one of the embodiments, the integrated circuit 100 includes at least one second dummy pattern such as second dummy patterns 120a and 120b. The second dummy patterns 120a and 120b are disposed adjacent to the first dummy patterns 110a and 110b, respectively. As noted, the photolithographic process transferring the pattern of the fuse 100a from the mask layer to the substrate may distort the central portion 105 of the fuse 100a. Dummy patterns on the mask layer corresponding to the second dummy patterns 120a and 120b reduce the distortion as well as ensure local pattern density.

In at least one of the embodiments, the second dummy patterns 120a and 120b have lines 121, 123 and 127, 129, respectively. The second dummy pattern 120a has a space 125a between the lines 121 and 123; and the second dummy pattern 120b has a space 125b between the lines 127 and 129. The spaces 125a and 125b are adjacent to the spaces 115a and 115b of the first dummy patterns 110a and 110b, respectively. If a current flow melts the fuse 100a and the melted fuse material migrates to the lines 111 and/or 113 and further to the lines 121 and/or 123, the space 125a is capable of isolating the line 121 from the line 123, maintaining an open current flow path. The integrated circuit coupled with the fuse 100a can thus be programmed and operate. It is noted that the number and location of the spaces 125a and 125b shown in FIG. 1 are mere examples. One of skill in the art is able to change the number and/or modify the location to achieve a desired fuse element.

Referring again to FIG. 1, in yet another embodiment, the integrated circuit 100 includes at least one third dummy pattern such as third dummy patterns 130a and 130b. The third dummy patterns 130a and 130b reduce the distortion to the central portion 105 of the fuse 100a resulting from the photolithographic process as well as ensure local pattern density. In embodiments, the third dummy patterns 130a and 130b include a plurality of lines 131-133 and 136-138, respectively. The dummy patterns 130a and 130b continuously extend over the substrate. In other embodiments, the dummy patterns 130a and 130b include at least one space described above in conjunction with dummy patterns 110a and 110b.

It is noted that the positions of the spaces 115a, 115b, 125a, and 125b can be modified as long as the spaces 115a, 115b, 125a, and 125b can desirably break the current flow through the migrating fuse material. It is also noted that the patterns and numbers of the dummy patterns 110a-110b, 120a-120b, 130a-130b, and lines 111, 113, 117, 119, 121, 123, 127, 129, 131-133, and 136-138 are mere examples. The scope of the invention is not limited thereto. One of skill in the art is able to modify them to achieve a desired fuse pattern.

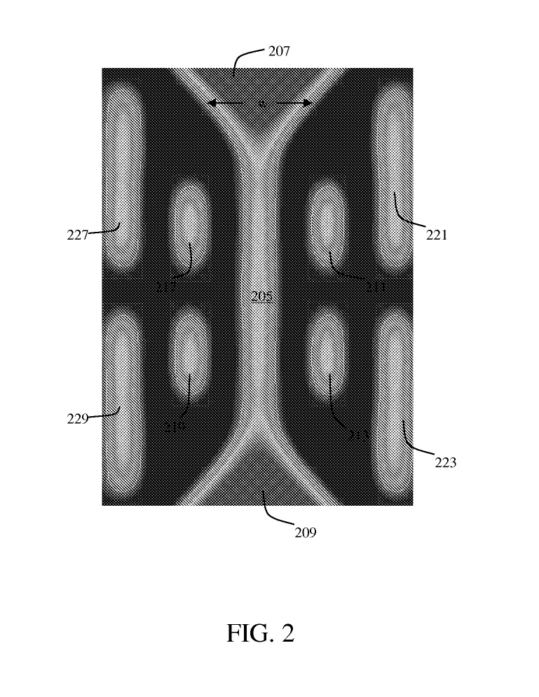

Referring again to FIG. 1, in one embodiment, the fuse 100a includes portions 107 and 109 between the first end 101 and the central portion 105 and between the second 103 and the central portion 105, respectively. As noted, the photolithographic process may distort the pattern of the central portion 105. The photolithographic process may also distort the pattern of joints between the first end 101 and the central portion 105 and between the second end 103 and the central portion 105. A pattern on the mask layer corresponding to the portion 107 is configured to eliminate or reduce the distortion at the joint of the first end 101 and the central portion 105. In some embodiments, the pattern on the mask layer corresponding to the portion 107 has a reduced width from the first end 101 to the central portion 105. The pattern on the mask layer corresponding to the portion 107 can be referred to as an optical proximate correction (OPC) technique. It is noted that the pattern of the portion 107 shown in FIG. 1 is merely illustrative. By transferring the pattern on the mask layer to the substrate, the final pattern of the portion 107 may be shown as the reference numeral 207 shown in FIG. 2. FIG. 2 is a drawing illustrating a simulation pattern corresponding to the fuse pattern of FIG. 1. Items of FIG. 2 that are the same or similar items in FIG. 1 are indicated by the corresponding reference numerals, which are reference numerals of FIG. 1 increased by 100. As shown, the final pattern of the portion 207 can have a width “w” gradually reducing from the first end (not shown in FIG. 2) to the central portion 205.

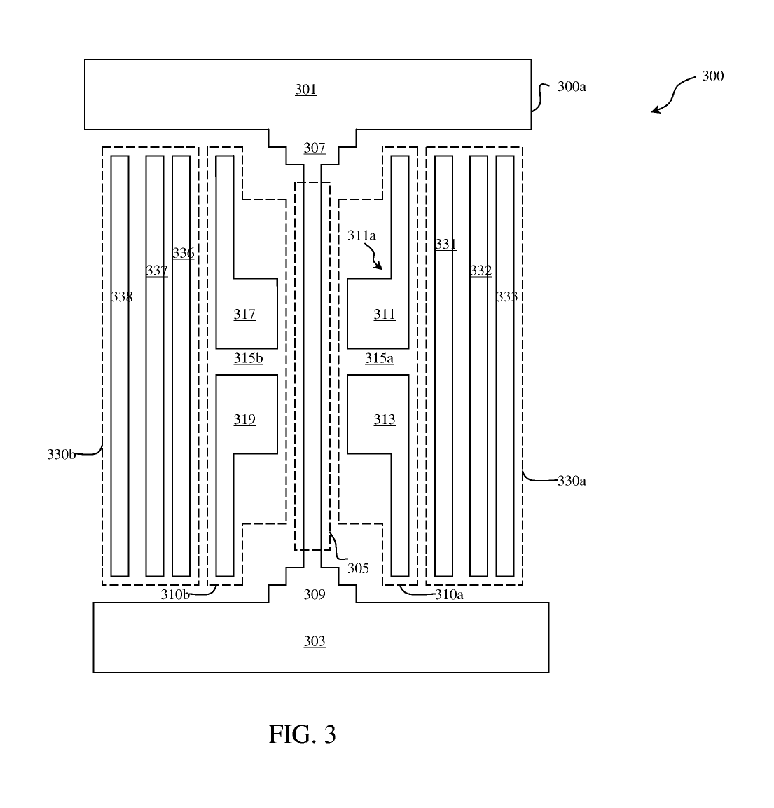

FIG. 3 is a drawing illustrating a fuse of an integrated circuit and another exemplary dummy patterns adjacent thereto. Items of FIG. 3 that are the same or similar items in FIG. 1 are indicated by corresponding reference numerals, which are reference numerals of FIG. 1 increased by 200. In one of the embodiments, the first dummy pattern 310a includes “L” shape dummy patterns 311 and 313. Each of the L-shape dummy patterns, e.g., the dummy pattern 311, have a corner, e.g., corner 311a, facing the portion 307 between the first end 301 and the central portion 305. Dummy patterns on the mask layer corresponding to the L-shape dummy pattern 307 eliminate or reduce distortions to the central portion 305 and/or the portion 307 of the fuse 300a resulting from the photolithographic process. It is noted that the shape of the dummy patterns 310a and 310b is merely an example. One of skill in the art is able to modify the shape of the dummy pattern to achieve a desired fuse pattern.

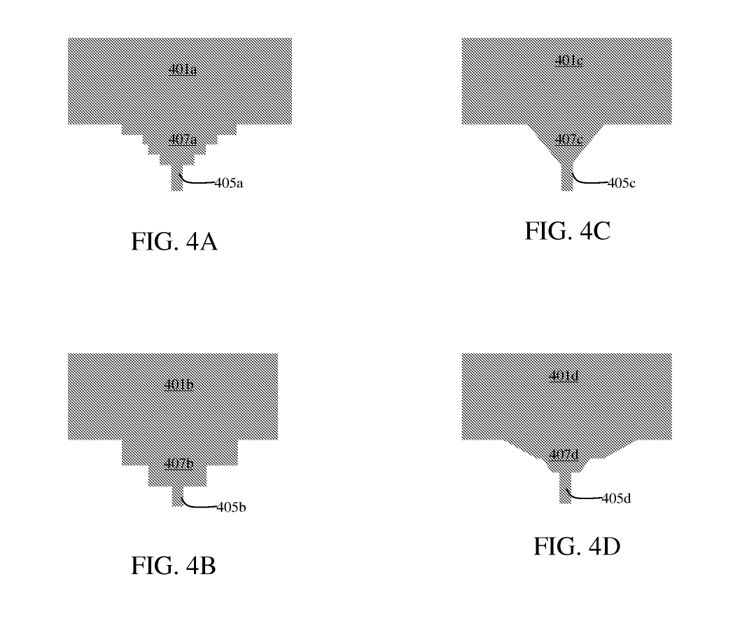

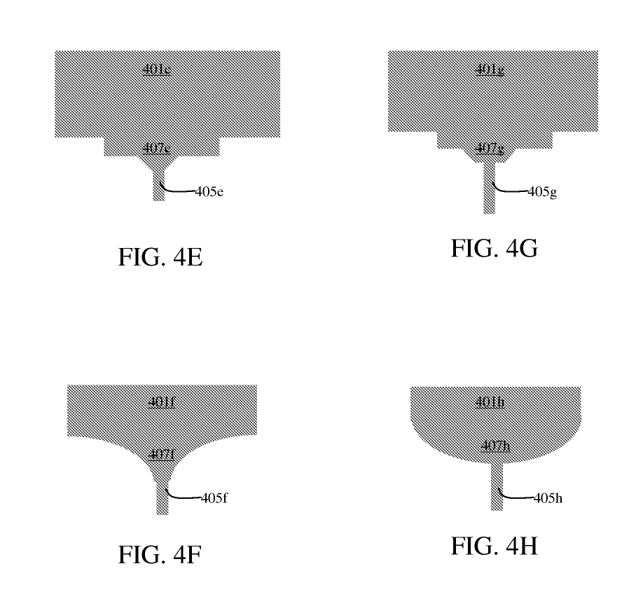

FIGS. 4A-4H are schematic drawings showing various exemplary patterns of potions between fuse ends and central portions usable in the embodiments depicted in FIGS. 1 and 3. Items of FIGS. 4A-4H that are the same or similar items in FIG. 1 are indicated by the corresponding reference numerals, which are reference numerals of FIG. 1 increased by 300 plus an alphabet changing from “a” to “h” for each drawing, respectively. It is noted that the patterns of the portions 407a-407h shown in FIGS. 4A-4H are mere examples and may be similar to those on mask layers. The final patterns of the portions 407a-407h on substrates may be similar to the portion 207 shown in FIG. 2 and/or changed according to the patterns on the mask layer. It is noted that the patterns of the portions 407a-407h between the fuse ends and the central portions are merely examples. One of skill in the art can modify the patterns to achieve a desired final pattern.

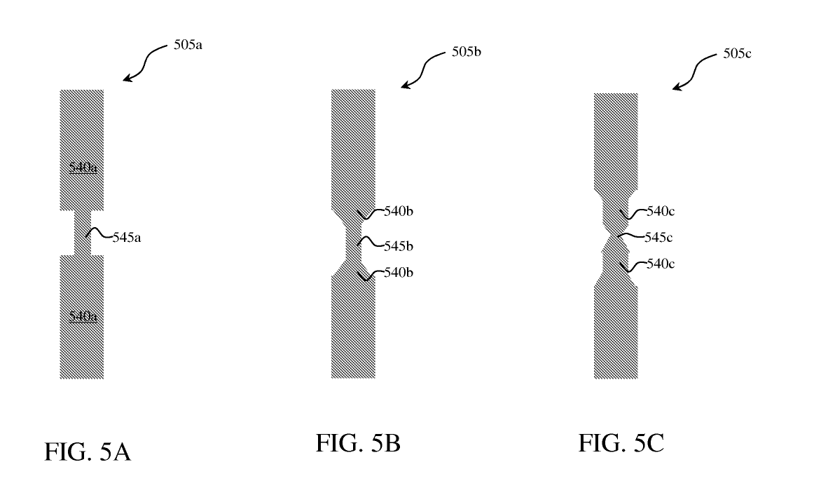

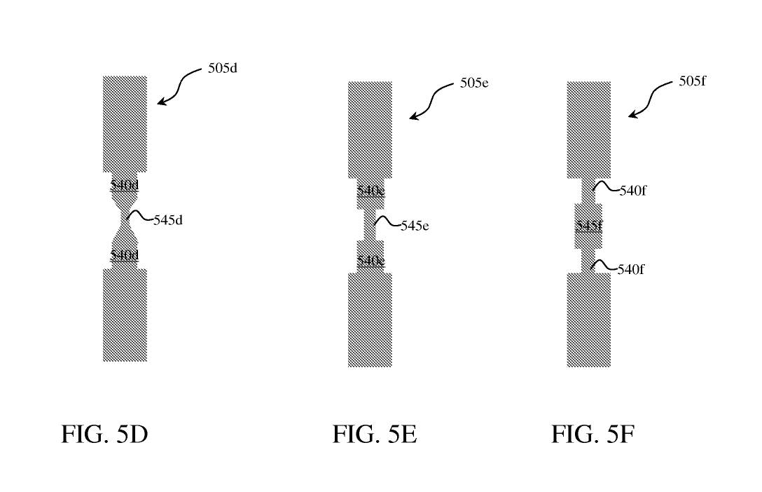

FIGS. 5A-5F are schematic drawings showing various exemplary patterns of the central portion of the fuse usable in conjunction with the embodiments depicted in FIGS. 1 and 3. Items of FIGS. 5A-5F that are the same or similar items in FIG. 1 are indicated by corresponding reference numerals, which are reference numerals of FIG. 1 increased by 400 plus an alphabet changing from “a” to “f” for each drawing, respectively. In embodiments depicted in FIGS. 5A-5E, the central portions 505a-505e have portions 545a-545e between portions 540a-540e, respectively. The width of the portions 545a-545e are smaller than the width of one of the portions 540a-540e, respectively. The portions 545a-545e are configured to melt if a high current flows through the central portions 505a-505e. In FIG. 5F, the central portion 505f has portion 545f between portions 540f, wherein the width of the portion 545f is larger than that of each of the portions 540f. In one embodiment, the portions 540f are configured to melt if a high current flows through the central portions 505f. It is noted that the patterns of the central portions 505a-505f are merely examples. One of skill in the art can modify the patterns to achieve a desired central portion of the fuse.

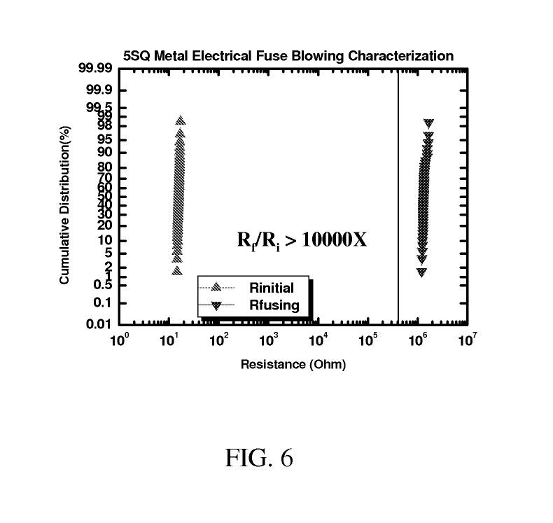

FIG. 6 is a drawing showing a relationship between resistance (Ω) and cumulative distribution (%) of exemplary fuses. As shown, a ratio of a final resistance (R_{fusing}) after fusing to an initial resistance (Rᵢₙᵢₜᵢₐₗ) can be about 10,000 or more. That is, the fuses described above in conjunction with FIGS. 1, 3, 4A-4H, and 5A-5F can be desirably blown if a high current flows through the fuse, and thus the integrated circuit coupled with the fuse is protected.

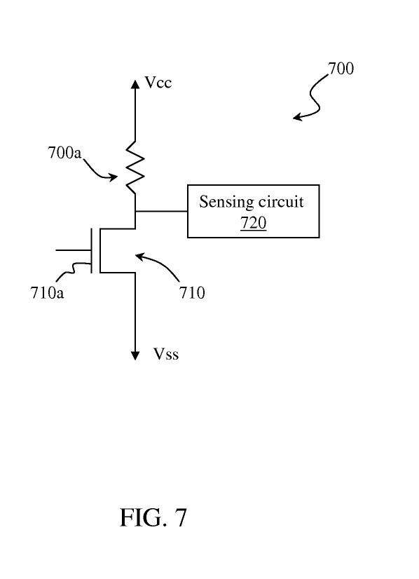

FIG. 7 is a schematic drawing showing a portion of an integrated circuit. In FIG. 7, in accordance with one of the embodiments, an integrated circuit 700 includes a fuse 700a, a metal-oxide-semiconductor field effect transistor (MOSFET) 710, and a sensing circuit 720. The fuse 700a is represented by a resistor symbol in the schematic diagram. The fuse 700a can be similar to the fuse 100a or 300a described above in conjunction with FIG. 1 or FIG. 3, respectively. A first terminal of the fuse 700a is coupled with a supply voltage, e.g., V_{cc}, and a second terminal is coupled with a drain terminal of the MOSFET 710, e.g., n-channel MOSFET. A source terminal of the MOSFET 710 is coupled with Vₛₛ or ground. In one of the embodiments, the MOSFET 710 is a driver device operable to supply a programming current and voltage drop across the fuse 700a. A control signal (not shown) is supplied to a gate terminal 710a of the MOSFET 710 that is operable to turn the MOSFET 710 ON or OFF. The sensing circuit 720 is coupled with the drain terminal of the MOSFET 710. The sensing circuit 720 is capable of sensing whether the fuse 700a is programmed. As noted, the resistance differential of the fuse 700a between its unprogrammed state and its programmed state is large. In one embodiment, the sensing circuit 720 senses if the fuse 700a is programmed by, for example, sensing a current flowing through the drain terminal of the MOSFET 710 or a voltage at the drain terminal of the MOSFET 700.

Although an n-channel MOSFET has been shown in this example, a p-channel MOSFET or another suitable driver device may be used. In embodiments, the driver device is simple in structure and can be formed by desired processing steps.

In operation, in accordance with one of the embodiments, if the fuse 700a is in the unprogrammed state, it exhibits a low resistance. The output voltage level at the drain terminal of the MOSFET 710 is substantially near the supply voltage level. To program the fuse 700a, a control signal (not shown) is supplied to the gate terminal 710a of the MOSFET 710 that can turn on the MOSFET 710. A voltage drop of substantially Vcc is applied across the fuse 700a and a current flows through the fuse 700a. The central portion of the fuse 700a is forced to bear the current flow and thus melts or is blown. A discontinuity is formed in the fuse 700a. The fuse 700a becomes an open circuit or its resistance becomes very high. In one embodiment, the sensing circuit 720 detects a voltage level approximating Vcc if the fuse 700a is in an unprogrammed state, and a floating or very low voltage level if the fuse 700a is in a programmed state.

In embodiments, the fuse 700a has a desired programming condition. For example, a desired programming potential and/or current can desirably convert the fuse 700a from an unprogrammed state with a low resistance to a programmed state with a high resistance.

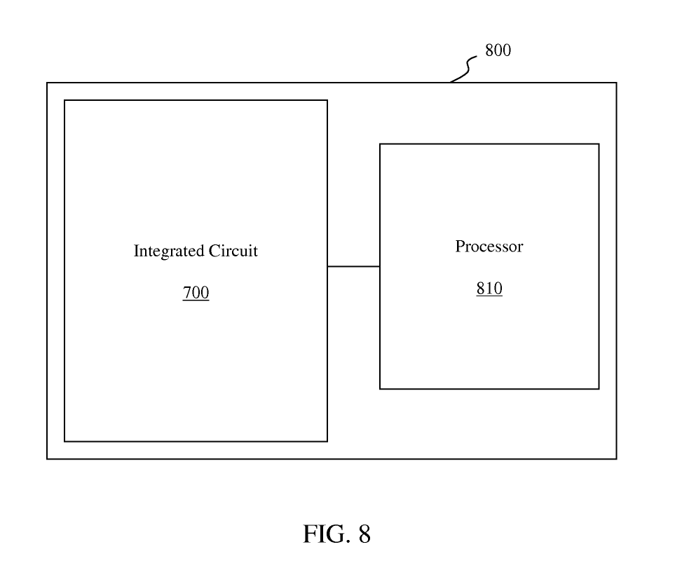

FIG. 8 is schematic drawing showing a system including an exemplary integrated circuit. In FIG. 8, a system 800 can include a processor 810 coupled with the integrated circuit 700. The processor 810 is capable of accessing the integrated circuit 700. In embodiments, the processor 810 can be a processing unit, central processing unit, digital signal processor, or other processor.

In some embodiments, the processor 810 and the integrated circuit 700 are formed within a system that is physically and electrically coupled with a printed wiring board or printed circuit board (PCB) to form an electronic assembly. In another embodiment, the electronic assembly is part of an electronic system such as computers, wireless communication devices, computer-related peripherals, entertainment devices, or the like.

In some embodiments, the system 800 including the integrated circuit 700 provides an entire system in one IC, so-called system on a chip (SOC) or system on integrated circuit (SOIC) devices. These SOC devices provide, for example, all of the circuitry needed to implement a cell phone, personal data assistant (PDA), digital VCR, digital camcorder, digital camera, MP3 player, or the like in a single integrated circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a fuse over a substrate, the fuse having a first end, a second end, and a central portion between the first end and the second end; and
a first dummy pattern disposed adjacent to each side of the central portion of the fuse.

2. The integrated circuit of claim 1, wherein the first dummy pattern has a space adjacent to the central portion of the fuse.

3. The integrated circuit of claim 1 further comprising a second dummy pattern disposed adjacent to the first dummy pattern.

4. The integrated circuit of claim 3, wherein the second dummy pattern has a space adjacent to the space of the first dummy pattern.

5. The integrated circuit of claim 1 further comprising a third dummy pattern, wherein the third dummy pattern continuously extends over the substrate.

6. The integrated circuit of claim 1, wherein the fuse has a first portion between the first end and the central portion, and a width of the first portion decreases from the first end towards the central portion.

7. The integrated circuit of claim 6, wherein the first dummy pattern includes at least one “L” shape pattern and a corner of the “L” shape pattern faces to the first portion of the fuse.

8. The integrated circuit of claim 1, wherein the central portion of the fuse has a first portion and two second portions, the first portion disposed between the two second portions, and a width of the first portion is less than one of the second portions.

9. The integrated circuit of claim 1, wherein the central portion of the fuse has a first portion and two second portions, the first portion disposed between the two second portions, and a width of the first portion is larger than one of the second portions.

10. A system comprising:
a processor; and
an integrated circuit coupled with the processor, the integrated circuit includes:
a fuse over a substrate, the fuse having a first end, a second end, and a central portion between the first end and the second end; and
a first dummy pattern disposed adjacent to each side of the central portion of the fuse.

11. The system of claim 10, wherein the first dummy pattern has a space adjacent to the central portion of the fuse.

12. The system of claim 10, wherein the integrated circuit further comprises a second dummy pattern disposed adjacent to the first dummy pattern.

13. The system of claim 12, wherein the second dummy pattern has a space adjacent to the space of the first dummy pattern.

14. The system of claim 10, wherein the integrated circuit further comprises a third dummy pattern and the third dummy pattern continuously extends over the substrate.

15. The system of claim 10, wherein the fuse has a first portion between the first end and the central portion, and a width of the first portion decreases from the first end towards the central portion.

16. The system of claim 15, wherein the first dummy pattern includes at least one “L” shape pattern and a corner of the “L” shape pattern faces to the first portion of the fuse.

17. The system of claim 10, wherein the central portion of the fuse has a first portion and two second portions, the first portion disposed between two second portions, and a width of the first portion is less than one of the second portions.

18. The system of claim 10, wherein the central portion of the fuse has a first portion and two second portions, the first portion disposed between two second portions, and a width of the first portion is larger than one of the second portions.
